(19) United States
(12) Patent Application Publication
(10) Pub. No.: US 2013/0249607 A1
(43) Pub. Date: Sep. 26, 2013

(54) BOOTSTRAPPED SWITCH CIRCUIT AND DRIVING METHOD THEREOF

(71) Applicant: FAIRCHILD KOREA SEMICONDUCTOR LTD., Bucheon (KR)

(72) Inventors: Gyoung-Soo PARK, Seoul (KR); Seung-Woo HONG, Seoul (KR); Moonsik SONG, Bucheon-si (KR); Sehwan KIM, Bucheon-Si (KR)

(73) Assignee: Fairchild Korea Semiconductor Ltd., Bucheon (KR)

(21) Appl. No.: 13/850,563

(22) Filed: Mar. 26, 2013

(30) Foreign Application Priority Data
Mar. 26, 2012 (KR) 10-2012-0030807

(51) Int. Cl. H03K 17/30

(52) U.S. Cl. CPC H03K 17/30
USPC 327/109

(57) ABSTRACT

The present invention relates to a bootstrap switch circuit and a driving method thereof. The bootstrap switch circuit includes: an input transistor including a first electrode for receiving an input voltage; an output transistor including a second electrode connected to a second electrode of the input transistor, and a first electrode for outputting an output voltage; a control transistor including a control electrode connected to the second electrode of the input transistor and the second electrode of the output transistor, and a first electrode for receiving a power supply voltage; and a level shifter including a power input terminal connected to the second electrode of the control transistor, an output terminal connected to a control electrode of the input transistor and a control electrode of the output transistor, and an input terminal for receiving a switch control signal. The level shifter turns on the input transistor and the output transistor when the switch control signal is an enable level, and it turns off the input transistor and the output transistor when the switch control signal is a disable level.

### CROSS-REFERENCE TO RELATED APPLICATION

This application claims priority to and the benefit of Korean Patent Application No. 10-2012-0030807 filed in the Korean Intellectual Property Office on Mar. 26, 2012, the entire contents of which are incorporated herein by reference.

### BACKGROUND OF THE INVENTION

(a) Field of the Invention

The present invention relates to a bootstrap switch circuit and a driving method thereof.

(b) Description of the Related Art

FIG. 1 shows a switch circuit for outputting an input voltage as an output voltage according to a switch control signal.

As shown in FIG. 1, the switch circuit includes PMOS transistors P1 and P2. Gate electrodes of the PMOS transistors P1 and P2 are connected with each other, and a switch control signal is input to the gate electrodes of the PMOS transistors P1 and P2.

An input voltage is input to a drain electrode of the PMOS transistor P1, and a source electrode of the PMOS transistor P1 is connected to a source electrode of the PMOS transistor P2. An output voltage is output through a drain electrode of the PMOS transistor P2.

A bootstrap switch circuit shown in FIG. 6 disclosed by U.S. Pat. No. 7,952,419 requires a bidirectional circuit element. Gate-source voltages of the PMOS transistors P1 and P2 are determined by a direction of a current flowing to the bidirectional circuit configuration, and the PMOS transistors P1 and P2 are switched according to the gate-source voltages.

Further, a switching rate of the bootstrap switch circuit disclosed in U.S. Pat. No. 7,952,419 is determined by a bias current IA (the current shown in FIG. 6 of the U.S. Patent).

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a bootstrap switch circuit with a constant switching rate irrespective of a bias current without a bidirectional circuit, and a driving method thereof.

An exemplary embodiment of the present invention provides a bootstrap switch circuit including: an input transistor including a first electrode for receiving an input voltage; an output transistor including a second electrode connected to a second electrode of the input transistor, and a first electrode for outputting an output voltage; a control transistor including a control electrode connected to the second electrode of the input transistor and the second electrode of the output transistor, and a first electrode for receiving a power supply voltage; and a level shifter including a power input terminal connected to the second electrode of the control transistor, an output terminal connected to a control electrode of the input transistor and a control electrode of the output transistor, and an input terminal for receiving a switch control signal.

The level shifter turns on the input transistor and the output transistor when the switch control signal is an enable level, and it turns off the input transistor and the output transistor when the switch control signal is a disable level.

The level shifter includes: a first transistor including a control electrode for receiving the switch control signal, a first electrode electrically connected to the control electrode of the input transistor and the control electrode of the output transistor, and a grounded second electrode; a second transistor including a control electrode for receiving an inverted switch control signal, a first electrode electrically connected to a first node, and a grounded second electrode; a third transistor including a control electrode connected to the first node, a first electrode connected to a control electrode of the input transistor and a control electrode of the output transistor, and a second electrode connected to the power input terminal; and a fourth transistor including a control electrode connected to the control electrode of the input transistor and the control electrode of the output transistor, a first electrode connected to the first node, and a second electrode connected to the power input terminal.

The level shifter further includes: a fifth transistor connected among the control electrode of the input transistor, the control electrode of the output transistor, and the first electrode of the first transistor; and a sixth transistor connected between the first node and the first electrode of the second transistor.

The bootstrap switch circuit further includes a bias current source connected to the control electrode of the fifth transistor and a control electrode of the sixth transistor, and turning on the fifth transistor and the sixth transistor.

The bootstrap switch circuit further includes a zener diode connected among the power input terminal, the control electrode of the fifth transistor, and the control electrode of the sixth transistor.

When the switch control signal has an enable level and the zener diode is turned on by the input voltage, control electrode voltages of the input transistor and the output transistor are reduced to a voltage that is generated by adding the threshold voltage of the fifth transistor to a voltage generated by subtracting the breakdown voltage of the zener diode from the power input terminal voltage.

When the switch control signal has the enable level and the zener diode is not turned on, the control electrode voltages of the input transistor and the output transistor are reduced to a voltage that is generated by adding the threshold voltage of the fifth transistor to the control electrode voltage of the fifth transistor.

An absolute value of the threshold voltage of the control transistor is less than absolute values of threshold voltages of the input transistor and the output transistor.

Another embodiment of the present invention provides a method for driving a bootstrap switch circuit including an input transistor, an output transistor including a control electrode connected to a control electrode of the input transistor and a first electrode connected to a first electrode of the input transistor, a control transistor including a control electrode connected to the first electrode of the input transistor and the first electrode of the output transistor, and a level shifter.

The method includes: controlling a first current to flow between a first power terminal connected to the level shifter and the control electrode by an enable-level switch control signal; changing a gate voltage of the control electrode to a level for turning on the input transistor and the output transistor by the first current; controlling a second current to flow to the control electrode and a second power terminal connected to the level shifter by a disable-level switch control signal; and changing the gate voltage to a level for turning off the input transistor and the output transistor by the second current.

The second power terminal and a first electrode of the control switch are connected with each other.

The changing of a gate voltage to a turn-off level includes reducing the gate voltage to a voltage from a control electrode voltage of the control transistor by a threshold voltage of the control transistor by the second current, and an absolute value of the threshold voltage of the control transistor is less than absolute values of the threshold voltages of the input transistor and the output transistor.

The method further includes, when the second power terminal voltage is increased by an input voltage that is input to the input transistor, turning on a zener diode and reducing the voltage at the control electrode by a breakdown voltage of the zener diode.

Yet another embodiment of the present invention provides a bootstrap switch circuit including: an input transistor for receiving an input voltage; an output transistor for outputting the input voltage transmitted by the input transistor as an output voltage; a control transistor for reducing a voltage at a first node of the input transistor and the output transistor by a first threshold voltage and outputting the reduced voltage as a first power supply voltage; and a level shifter connected to the first power supply voltage and the second power supply voltage, receiving a switch control signal, and transmitting a first-level gate voltage or a second-level gate voltage to a control electrode of the input transistor and a control electrode of the output transistor according to the switch control signal.

The second-level gate voltage represents a level for turning off the input transistor and the output transistor, and it is the first power supply voltage level.

An absolute value of the first threshold voltage is less than absolute values of threshold voltages of the input transistor and the output transistor.

The level shifter includes: a first transistor switched according to the switch control signal; a second transistor switched according to an inverted switch control signal; a third transistor turned on by a second power supply voltage transmitted by the second transistor; and a fourth transistor turned on by a second power supply voltage transmitted by the first transistor.

The fourth transistor is turned off by the first power supply voltage when the third transistor is turned on, and the third transistor is turned off by the first power supply voltage when the fourth transistor is turned on.

The level shifter further includes a fifth transistor connected between the first transistor and the third transistor, and a sixth transistor connected between the second transistor and the fourth transistor.

The bootstrap switch circuit further includes: a bias current source connected to a control electrode of the fifth transistor, a control electrode of the sixth transistor, and the second power supply voltage; and a zener diode connected among the first power supply voltage, the control electrode of the fifth transistor, and the control electrode of the sixth transistor.

The zener diode is turned on by the input voltage when the switch control signal has an enable level, and the first-level gate voltage represents a voltage that is acquired by subtracting a breakdown voltage of the zener diode from the first power supply voltage and adding a threshold voltage of the fifth transistor thereto.

When the switch control signal has an enable level and the zener diode is not turned on, the first-level gate voltage represents a voltage acquired by adding a threshold voltage of the fifth transistor to the control electrode voltage of the fifth transistor.

According to the exemplary embodiments of the present invention, a bootstrap switch circuit for providing a constant switching rate irrespective of the bias current without the bidirectional circuit and the driving method thereof are provided.

### BRIEF DESCRIPTION OF THE DRAWINGS

FIG. 1 shows a switch circuit for outputting an input voltage as an output voltage according to a switch control signal.

FIG. 2 shows a bootstrap switch circuit according to an exemplary embodiment of the present invention.

FIG. 3 shows a waveform diagram of a waveform of a switch control signal according to an exemplary embodiment of the present invention.

FIG. 4 shows a waveform diagram for a current flowing to an equivalent capacitor.

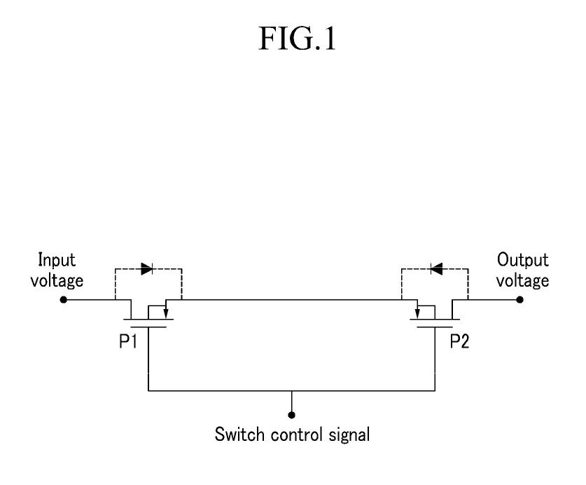

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise” and variations such as “comprises” or “comprising” will be understood to imply the inclusion of stated elements but not the exclusion of any other elements.

Exemplary embodiments of the present invention will now be described with reference to accompanying drawings.

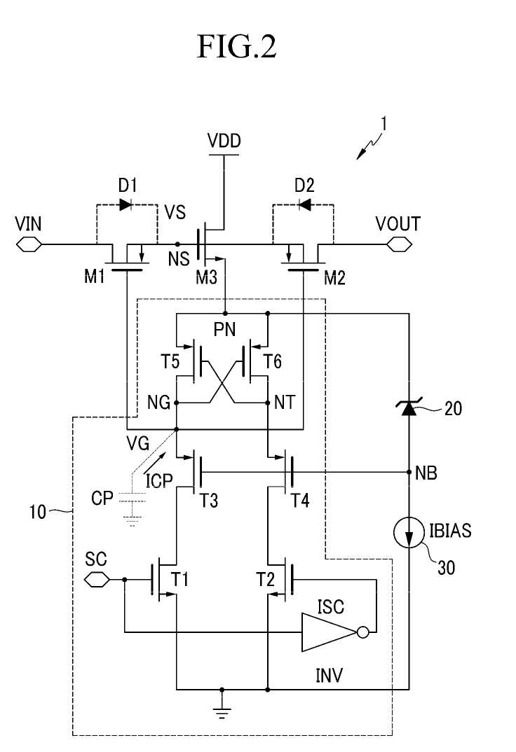

FIG. 2 shows a bootstrap switch circuit according to an exemplary embodiment of the present invention.

The bootstrap switch circuit 1 includes an input transistor Ml, an output transistor M2, a control transistor M3, a level shifter 10, a zener diode 20, and a bias current source 30.

The input transistor M1 includes a drain electrode for receiving an input voltage (VIN), a gate electrode connected to a gate node (NG), and a source electrode connected to a source node (NS).

The output transistor M2 includes a source electrode connected to the source node (NS), a gate electrode connected to the gate node (NG), and a drain electrode for outputting an output voltage (VOUT).

The control transistor M3 includes a drain electrode for receiving a power supply voltage (VDD), a gate electrode connected to the source node (NS), and a source electrode connected to a power input terminal (PN) of the level shifter 10.

The level shifter 10 receives a switch control signal (SC), and changes a voltage difference between a gate voltage (VG) and a voltage (VS) at the source node (NS) (hereinafter, source voltage) into a voltage that corresponds to a turn-on state or a turn-off state according to the switch control signal (SC).

The level shifter 10 includes a plurality of transistors (T1-T6) and an inverter (INV).

The transistor T1 includes a gate electrode for receiving a switch control signal (SC), a grounded source electrode, and a drain electrode electrically connected to the gate node (NG).

The inverter (INV) inverts the switch control signal (SC) to generate an inverted switch control signal (ISC).

The transistor T2 includes a gate electrode for receiving an inverted switch control signal (ISC), a grounded source electrode, and a drain electrode electrically connected to the node (NT).

In the exemplary embodiment of the present invention, the transistor T1 is connected to the gate node (NG) through the transistor T3 and the transistor T2 is connected to the node (NT) through the transistor T4, but the present invention is not restricted thereto, and the transistors T1 and T2 can be connected to the gate node (NG) and the node (NT) without the transistor T3 or the transistor T4. In this instance, the bootstrap switch circuit 1 may not include the bias current source 30.

The transistor T3 (or the transistor T4) can be controlled so that the gate voltage (VG) (or the voltage at the node (NT)) may not be very much smaller than the source voltage VS, i.e., the difference between the two voltages VS and VG may not be very large.

A voltage at the gate node (NG) (or the node (NT)) is greater when the transistor T3 (or the transistor T4) is provided. That is, the gate voltage (VG) (or the voltage at the node (NT)) is controlled to be not too low by the transistor T3 (or the transistor T4).

The transistor T3 includes a gate electrode connected to the node (NB), a source electrode connected to the gate node (NG), and a drain electrode connected to the drain electrode of the transistor T1.

The transistor T4 includes a gate electrode connected to the node (NB), a source electrode connected to the node (NT), and a drain electrode connected to the drain electrode of the transistor T2.

The transistor T5 includes a source electrode connected to the power input terminal (PN), a gate electrode connected to the node (NT), and a drain electrode connected to the gate node (NG).

The transistor T6 includes a source electrode connected to the power input terminal (PN), a gate electrode connected to the gate node (NG), and a drain electrode connected to the node (NT).

The zener diode 20 is connected between the power input terminal (PN) and the node (NB), and controls each of the source-gate voltages of the transistor T3 and the transistor T4 with a zener voltage. The zener diode 20 includes a cathode connected to the power input terminal (PN), and an anode connected to the node (NB).

The bias current source 30 is connected between the node (NB) and the ground, and sinks the bias current to the ground from the gate electrodes of the transistor T3 and the transistor T4. The transistor T3 and the transistor T4 are maintained to be turned on.

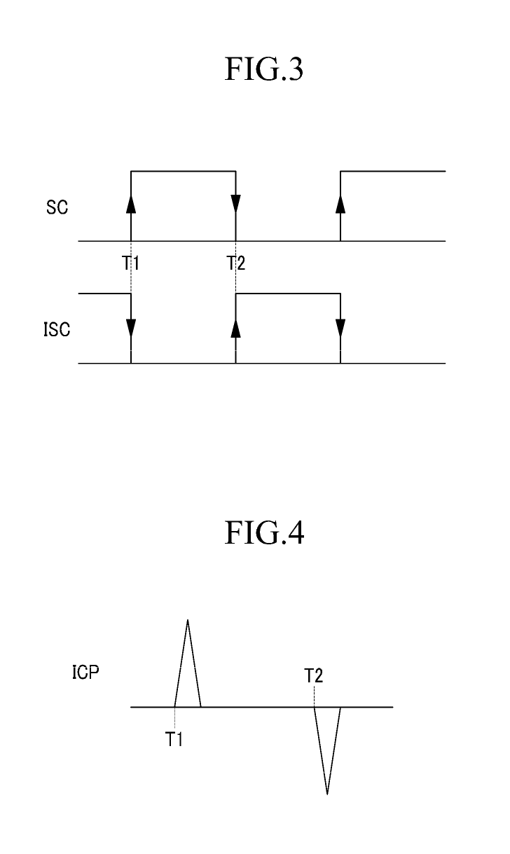

An operation of a bootstrap switch circuit according to an exemplary embodiment of the present invention will now be described with reference to FIG. 3 and FIG. 4.

FIG. 3 shows a waveform diagram of a waveform of a switch control signal according to an exemplary embodiment of the present invention.

As shown in FIG. 3, at the time T1, the switch control signal (SC) rises to a high level, which is an enable level. The enable level represents a level for turning on the input transistor M1 and the output transistor M2.

At the time T1, the transistor T1 is turned on and the transistor T2 is turned off by an inverted switch control signal (ISC). The transistor T3 is turned on, and the gate voltage (VG) is changed into a predetermined voltage by the input voltage (VIN).

In detail, when the zener diode 20 is turned on by the input voltage (VIN), the gate voltage (VG) is reduced to be a specific voltage. The specific voltage is given as (voltage at the power input terminal (PN))−(zener voltage)+(gate-source voltage at the transistor T3). The zener voltage represents a breakdown voltage of the zener diode 20.

When the input voltage (VIN) is not high and the zener diode 20 is not turned on, it becomes (voltage at the node (NB))+(gate-source voltage of the transistor T3). The voltage at the node (NB) has a ground level.

When the zener diode 20 is turned on or off, the level of the gate voltage (VG) is very much less than the source voltage VS, and the input transistor M1 and the output transistor M2 are turned on.

By the low-level gate voltage (VG), the input transistor M1 and the output transistor M2 are turned on and the input voltage (VIN) is output as the output voltage (VOUT). In this instance, by the low-level gate voltage (VG), the transistor T6 is turned on, the gate electrode and the source electrode of the transistor M5 are connected with each other, and the transistor T5 is turned off.

The voltage at the power input terminal (PN) is determined by the gate voltage of the control transistor M3, which is the source voltage VS. The voltage at the power input terminal (PN) represents a voltage that is less than the gate voltage at the control transistor M3 by a threshold voltage Vth1 of the control transistor M3.

When the switch control signal (SC) becomes the enable level at the time T1, a current (ICP) that flows to the ground through the transistor T3 and the transistor T1 is generated. The equivalent capacitor (CP) shown in FIG. 2 is quickly discharged by the corresponding current.

The equivalent capacitor (CP) shows capacitance between the gate node (NG) and the ground in a circuital manner.

FIG. 4 shows a waveform diagram for a current flowing to an equivalent capacitor.

As shown in FIG. 4, at the time T1, a high current (ICP) is generated to flow for a short time. The equivalent capacitor (CP) is quickly discharged by the high current (ICP).

At the time T2, the switch control signal (SC) falls to the low level, which is a disable level. The disable level represents a level for turning off the input transistor M1 and the output transistor M2.

At the time T2, the transistor T2 is turned on by the inverted switch control signal (ISC), and the transistor T1 is turned off. The transistor T4 is turned on so the voltage at the node (NT) is changed to a predetermined voltage according to the input voltage (VIN).

In detail, when the zener diode 20 is turned on by the high input voltage (VIN), the voltage at the node (NT) is reduced to be a specific voltage.

When the input voltage (VIN) is not high and the zener diode 20 is not turned on, the voltage becomes (voltage at the node (NB))+(gate-source voltage at the transistor T4). The voltage at the node (NB) has the ground level.

When the zener diode 20 is turned on or off, the voltage level of the node (NT) is very much lower than the voltage at the power input terminal (PN). Therefore, the transistor T5 is turned on, and the gate electrode and the source electrode of the transistor T6 are connected to each other to be turned off. The gate voltage (VG) becomes the voltage at the power input terminal (PN) through the turned-on transistor T5.

The voltage at the power input terminal (PN) represents a voltage (VS−Vth1) that is less than the gate voltage of the control transistor M3 by the threshold voltage Vth1. The source-gate voltages of the input transistor M1 and the output transistor M2 become the threshold voltage Vth1. An absolute value of the threshold voltage Vth1 is less than the absolute value of the threshold voltage Vth2.

Therefore, the input transistor M1 and the output transistor M2 are turned off.

The equivalent capacitor (CP) is charged by the high current (ICP) that flows through the turned-on transistor T5 at the time T2 so the gate voltage (VG) rises to the voltage (VS−Vth1). As shown in FIG. 4, the current (ICP) is generated at the time T2 and it flows for a short time.

A basic direction of the current (ICP) is set to be in a direction to the ground from the equivalent capacitor (CP), and the current (ICP) flowing at the time T2 is shown with a negative value.

Hence, according to the exemplary embodiments of the present invention, the high current is generated when the input transistor M1 and the output transistor M2 are turned on and turned off so the switching period is very much shorter. The switching period represents a changing period from the turn-on to the turn-off state and vice versa. Therefore, the switching rate of the bootstrap switch circuit is fast because of the high current.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A bootstrap switch circuit comprising:
an input transistor including a first electrode for receiving an input voltage;
an output transistor including a second electrode connected to a second electrode of the input transistor, and a first electrode for outputting an output voltage;
a control transistor including a control electrode connected to the second electrode of the input transistor and the second electrode of the output transistor, and a first electrode for receiving a power supply voltage; and
a level shifter including a power input terminal connected to the second electrode of the control transistor, an output terminal connected to a control electrode of the input transistor and a control electrode of the output transistor, and an input terminal for receiving a switch control signal, wherein
the level shifter turns on the input transistor and the output transistor when the switch control signal is an enable level, and it turns off the input transistor and the output transistor when the switch control signal is a disable level.

2. The bootstrap switch circuit of claim 1, wherein
the level shifter includes:
a first transistor including a control electrode for receiving the switch control signal, a first electrode electrically connected to the control electrode of the input transistor and the control electrode of the output transistor, and a grounded second electrode;
a second transistor including a control electrode for receiving an inverted switch control signal, a first electrode electrically connected to a first node, and a grounded second electrode;
a third transistor including a control electrode connected to the first node, a first electrode connected to a control electrode of the input transistor and a control electrode of the output transistor, and a second electrode connected to the power input terminal; and
a fourth transistor including a control electrode connected to the control electrode of the input transistor and the control electrode of the output transistor, a first electrode connected to the first node, and a second electrode connected to the power input terminal.

3. The bootstrap switch circuit of claim 2, wherein
the level shifter further includes:
a fifth transistor connected among the control electrode of the input transistor, the control electrode of the output transistor, and the first electrode of the first transistor; and
a sixth transistor connected between the first node and the first electrode of the second transistor.

4. The bootstrap switch circuit of claim 3, further including
a bias current source connected to the control electrode of the fifth transistor and a control electrode of the sixth transistor, and turning on the fifth transistor and the sixth transistor.

5. The bootstrap switch circuit of claim 4, further including
a zener diode connected among the power input terminal, the control electrode of the fifth transistor, and the control electrode of the sixth transistor.

6. The bootstrap switch circuit of claim 5, wherein
when the switch control signal has an enable level and the zener diode is turned on by the input voltage, control electrode voltages of the input transistor and the output transistor are reduced to a voltage that is generated by adding the threshold voltage of the fifth transistor to a voltage generated by subtracting the breakdown voltage of the zener diode from the power input terminal voltage.

7. The bootstrap switch circuit of claim 5, wherein
when the switch control signal has the enable level and the zener diode is not turned on, the control electrode voltages of the input transistor and the output transistor are reduced to a voltage that is generated by adding the threshold voltage of the fifth transistor to the control electrode voltage of the fifth transistor.

8. The bootstrap switch circuit of claim 1, wherein
an absolute value of the threshold voltage of the control transistor is less than absolute values of threshold voltages of the input transistor and the output transistor.

9. A method for driving a bootstrap switch circuit including an input transistor, an output transistor including a control electrode connected to a control electrode of the input transistor and a first electrode connected to a first electrode of the input transistor, a control transistor including a control electrode connected to the first electrode of the input transistor and the first electrode of the output transistor, and a level shifter, the method comprising:
controlling a first current to flow between a first power terminal connected to the level shifter and the control electrode by an enable-level switch control signal;
changing a gate voltage of the control electrode to a level for turning on the input transistor and the output transistor by the first current;
controlling a second current to flow to the control electrode and a second power terminal connected to the level shifter by a disable-level switch control signal; and
changing the gate voltage to a level for turning off the input transistor and the output transistor by the second current, wherein
the second power terminal and a first electrode of the control switch are connected with each other.

10. The method of claim 9, wherein
the changing of a gate voltage to a turn-off level includes reducing the gate voltage to a voltage from a control electrode voltage of the control transistor by a threshold voltage of the control transistor by the second current, and
an absolute value of the threshold voltage of the control transistor is less than absolute values of the threshold voltages of the input transistor and the output transistor.

11. The method of claim 10, further including
when the second power terminal voltage is increased by an input voltage that is input to the input transistor, turning on a zener diode and reducing the voltage at the control electrode by a breakdown voltage of the zener diode.

12. A bootstrap switch circuit comprising:
an input transistor for receiving an input voltage;
an output transistor for outputting the input voltage transmitted by the input transistor as an output voltage;
a control transistor for reducing a voltage at a first node of the input transistor and the output transistor by a first threshold voltage and outputting the reduced voltage as a first power supply voltage; and
a level shifter connected to the first power supply voltage and the second power supply voltage, receiving a switch control signal, and transmitting a first-level gate voltage or a second-level gate voltage to a control electrode of the input transistor and a control electrode of the output transistor according to the switch control signal, wherein
the second-level gate voltage represents a level for turning off the input transistor and the output transistor, and it is the first power supply voltage level.

13. The bootstrap switch circuit of claim 12, wherein
an absolute value of the first threshold voltage is less than absolute values of threshold voltages of the input transistor and the output transistor.

14. The bootstrap switch circuit of claim 13, wherein
the level shifter includes:
a first transistor switched according to the switch control signal;
a second transistor switched according to an inverted switch control signal;
a third transistor turned on by a second power supply voltage transmitted by the second transistor; and
a fourth transistor turned on by a second power supply voltage transmitted by the first transistor, wherein
the fourth transistor is turned off by the first power supply voltage when the third transistor is turned on, and the third transistor is turned off by the first power supply voltage when the fourth transistor is turned on.

15. The bootstrap switch circuit of claim 14, wherein
the level shifter further includes:
a fifth transistor connected between the first transistor and the third transistor; and
a sixth transistor connected between the second transistor and the fourth transistor.

16. The bootstrap switch circuit of claim 15, further including:
a bias current source connected to a control electrode of the fifth transistor, a control electrode of the sixth transistor, and the second power supply voltage; and
a zener diode connected among the first power supply voltage, the control electrode of the fifth transistor, and the control electrode of the sixth transistor.

17. The bootstrap switch circuit of claim 16, wherein
the zener diode is turned on by the input voltage when the switch control signal has an enable level, and the first-level gate voltage represents a voltage that is acquired by subtracting a breakdown voltage of the zener diode from the first power supply voltage and adding a threshold voltage of the fifth transistor thereto.

18. The bootstrap switch circuit of claim 16, wherein
when the switch control signal has an enable level and the zener diode is not turned on, the first-level gate voltage represents a voltage acquired by adding a threshold voltage of the fifth transistor to the control electrode voltage of the fifth transistor.
